(19) United States
(12) Patent Application Publication
(10) Pub. No.: US 2007/0178678 A1
(43) Pub. Date: Aug. 2, 2007

(54) Methods of implanting ions and ion sources used for same

(75) Inventors: Christopher Hatem, Salisbury, MA (US); Jonathan England, Horsham (GB); Larry Sneddon, Newton Square, PA (US); Russell Low, Rowley, MA (US); Anthony Renau, West Newbury, MA (US); Alexander Perel, Danvers, MA (US); Kourosh Saadatmand, Merrimac, MA (US)

Correspondence Address: Mark Superko;Varian Semiconductor Equipment Associates, Inc., 35 Dory Lane, Gloucester, MA, 01930-2297, US

(73) Assignee: Varian Semiconductor Equipment Associates, Inc., Gloucester, MA (US)

(21) Appl. No.: 11/342,183

(22) Filed: Jan. 28, 2006

(51) Int. Cl. H01L 21/26

(52) U.S. Cl. 438/513; 257/E21.043

(57) ABSTRACT

Methods of ion implantation and ion sources used for the same are provided. The methods involve generating ions from a source feed gas that comprises multiple elements. For example, the source feed gas may comprise boron and at least two other elements (e.g., XₐB_{b}Y_{c}). The use of such source feed gases can lead to a number of advantages over certain conventional processes including enabling use of higher implant energies and beam currents when forming implanted regions having ultra-shallow junction depths. Also, in certain embodiments, the composition of the source feed gas may be selected to be thermally stable at relatively high temperatures (e.g., greater than 350° C.) which allows use of such gases in many conventional ion sources (e.g., indirectly heated cathode (IHC), Bernas) which generate such temperatures during use.

### FIELD OF INVENTION

The invention relates generally to ion implantation and, more particularly, to ion sources that use a boron-based source feed gas and methods associated with the same.

### BACKGROUND OF INVENTION

Ion implantation is a conventional technique for introducing dopants into materials such as semiconductor wafers. Dopants may be implanted in a material to form regions of desired conductivity. Such implanted regions can form active regions in resulting devices (e.g., semiconductor devices). Typically, during ion implantation, a source feed gas is ionized in an ion source. The ions are emitted from the source and may be accelerated to a selected energy to form an ion beam. The beam is directed at a surface of the material and the impinging ions penetrate into the bulk of the material and function as dopants that increase the conductivity of the material.

Conventional ion sources may have limitations under certain implantation conditions. For example, conventional ion sources may operate inefficiently at low extraction energies and/or low beam currents which may be used in implantation processes that form implanted regions having ultra-shallow junction depths. As a result, long implant times may be needed to achieve a desired implantation dose and, thus, throughput is adversely affected.

### SUMMARY OF INVENTION

Ion implantation methods and ion sources used for the same are provided.

In one aspect, a method of implanting ions is provided. The method comprises generating ions from a source feed gas comprising boron and at least two additional elements; and, implanting the ions in a material.

In another aspect, an ion source is provided. The ion source comprises a chamber housing defining a chamber; and, a source feed gas supply configured to introduce a source feed gas comprising boron and at least two additional elements into the chamber. The ion source is configured to ionize the source feed gas within the chamber.

In another aspect, a method of implanting ions is provided. The method comprises forming a source feed gas from a source feed material comprising boron and at least two additional elements. The method further comprises generating ions from the source feed gas; and implanting the ions in a material.

In another aspect, an ion source is provided. The ion source comprises a chamber housing defining a chamber; and a source feed gas supply configured to form a source feed gas from a source feed material comprising boron and at least two additional elements and introduce the source feed gas into the chamber. The ion source is configured to ionize the source feed gas within the chamber.

Other aspects, embodiments and features of the invention will become apparent from the following detailed description of the invention when considered in conjunction with the accompanying drawings. The accompanying figures are schematic and are not intended to be drawn to scale. In the figures, each identical, or substantially similar component that is illustrated in various figures is represented by a single numeral or notation. For purposes of clarity, not every component is labeled in every figure. Nor is every component of each embodiment of the invention shown where illustration is not necessary to allow those of ordinary skill in the art to understand the invention. All patent applications and patents incorporated herein by reference are incorporated by reference in their entirety. In case of conflict, the present specification, including definitions, will control.

### BRIEF DESCRIPTION OF THE DRAWINGS

FIG. 1 illustrates an ion implantation system according to an embodiment of the invention.

FIG. 2 illustrates an ion source according to an embodiment in the invention.

### DETAILED DESCRIPTION

Methods of ion implantation and ion sources used for the same are provided. The methods involve generating ions from a source feed gas that comprises multiple elements. For example, the source feed gas may comprise boron and at least two other elements. As described further below, the use of such source feed gases can lead to a number of advantages over certain conventional processes including enabling use of higher implant energies and beam currents when forming implanted regions having ultra-shallow junction depths. Also, in certain embodiments, the composition of the source feed gas may be selected to be thermally stable at relatively high temperatures (e.g., greater than 350° C.) which allows use of such gases in many conventional ion sources (e.g., indirectly heated cathode, Bernas) which generate such temperatures.

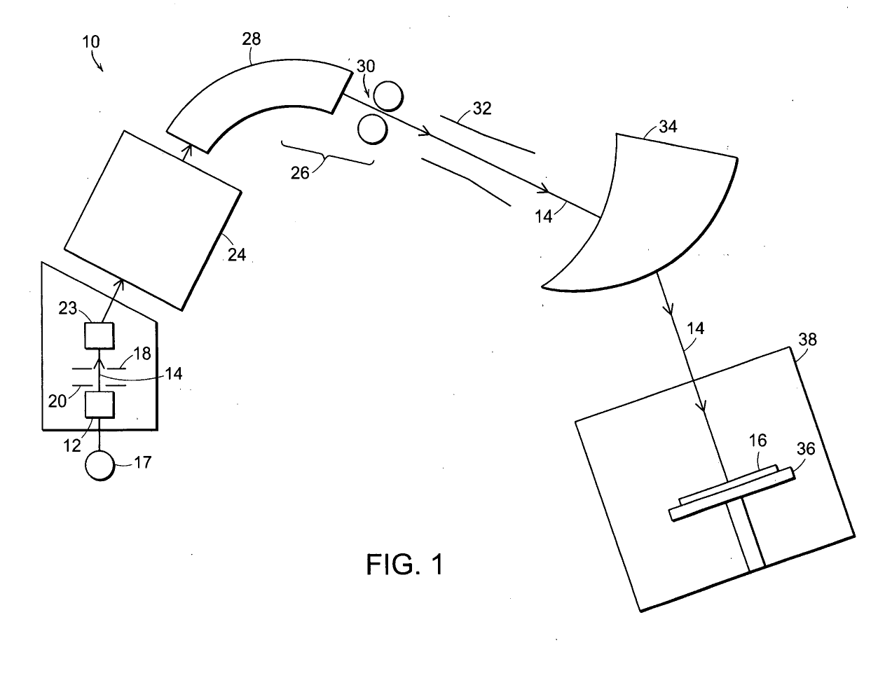

FIG. 1 illustrates an ion implantation system 10 according to an embodiment of the invention. The system includes an ion beam source 12 that generates an ion beam 14 which is transported through the system and impinges upon a wafer 16. The ion beam source includes a source feed gas supply 17. The source feed gas supply may generate the source feed gas from a source feed material, as described further below. Source feed gas from the supply is introduced into the ion beam source and is ionized to generate ionic species. As described further below, the source feed gas may comprise boron and at least two other elements (e.g., XₐB_{b}Y_{c}) according to certain embodiments of the invention. In the illustrative embodiment shown in FIG. 1, an extraction electrode 18 is associated with the ion beam source for extracting the ion beam from the source. A suppression electrode 20 may also be associated with the ion source.

The implantation system further includes a source filter 23 which removes undesired species from the beam. Downstream of the source filter, the system includes an acceleration/deceleration column 24 in which the ions in the beam are accelerated/decelerated to a desired energy, and a mass analyzer 26 which can remove energy and mass contaminants from the ion beam through use of a dipole analyzing magnet 28 and a resolving aperture 30. A scanner 32 may be positioned downstream of the mass analyzer and is designed to scan the ion beam across the wafer. The system includes an angle corrector magnet 34 to deflect ions to produce a scanned beam having parallel ion trajectories.

During implantation, the scanned beam impinges upon the surface of the wafer which is supported on a platen 36 within a process chamber 38. In general, the entire path traversed by the ion beam is under vacuum during implantation. The implantation process is continued until regions having the desired dopant concentration and junction depth are formed with the wafer.

It should be understood that features of the invention may be used in conjunction with any suitable ion implantation system or method. Accordingly, the system illustrated in FIG. 1 may include modifications. In some cases, the system may include additional components than those illustrated. In other cases, systems may not include all of the illustrated components. Suitable systems include implanters having a ribbon beam architecture, a scanned-beam architecture or a spot beam architecture (e.g., systems in which the ion beam is static and the wafer is scanned across the static beam). For example, suitable implanters have been described in U.S. Pat. Nos. 4,922,106, 5,350,926 and 6,313,475.

Though in some embodiments, it may be preferred to use ion sources of the invention in methods that form ultra-shallow junction depths (e.g., less than 25 nanometers), it should be understood that the invention is not limited in this regard. It should also be understood that the systems and methods may be used to implant ions in a variety of materials including, but not limited to, semiconductor materials (e.g., silicon, silicon-on-insulator, silicon germanium, III-V compounds, silicon carbide), as well as other material such as insulators (e.g., silicon dioxide) and polymer materials, amongst others.

As described above, source feed gas supply 17 introduces a source feed gas into the ion beam source. The source feed gas may comprise boron and at least two additional elements (i.e., elements that are different than boron and each other). In general, the additional (i.e., non-boron) elements of the source gas may be any suitable element including carbon, hydrogen, nitrogen, phosphorous, arsenic, antimony, silicon, tin, and germanium, amongst others. In some embodiments, it may be preferred that the source gas comprise boron, hydrogen and carbon. It should be understood that the source gas may also include more than two additional elements.

In general, the source feed gas may have any suitable chemical structure and the invention is not limited in this regard. For example, the source feed gas may be represented by the general formula XBY, wherein B represents boron, and X and Y each represent at least one element. In some cases, X and/or Y may represent single elements (e.g., X═C, Y═H); and, in other cases, X and/or Y may represent more than one element (e.g., X═NH₄, NH₃, CH₃). Also, it should be understood that the source feed gas XBY may be represented by other equivalent chemical formulas that, for example, may include the same elements in a different order such as BXY (e.g., B₃N₃H₆) or XYB. In some embodiments, the source feed gas may be represented by the XₐB_{b}Y_{c}, wherein a >0, b>0 and c>0.

In some cases, it may be preferred that Y in the above-noted formulas represents at least hydrogen (e.g., the source feed gas comprises XₐB_{b}H_{c}). It should be understood that, in some embodiments, derivatives of XₐB_{b}H_{c} may be used which contain other elements or groups of elements (e.g., CH₃) which replace hydrogen at X and/or B sites. The substituents may be any suitable inorganic or organic species.

In some cases, it may be preferred that X in the above-noted formulas represents at least carbon (e.g., the source feed gas comprises CₐB_{b}H_{c}). It should be understood that, in some embodiments, derivatives of CₐB_{b}H_{c} may be used which contain other elements or groups of elements which replace hydrogen at C and/or B sites). The substituents may be any suitable inorganic or organic species. In some cases, it may be preferred that the source feed gas comprise C₂B₁₀H₁₂.

In other embodiments, X in the above-noted formulas may be N, P, As, Sb, Si, Ge or Sn. For example, the source feed gas may comprise NₐB_{b}Y_{c} (e.g., NₐB₁₀H₁₂ or B₃N₃H₆), NₐB_{b}H_{c}, PₐB_{b}H_{c}, AsₐB_{b}H_{c}, SbₐB_{b}H_{c}, SiₐB_{b}H_{c}, GeₐB_{b}H_{c} and SnₐB_{b}H_{c}. It should be understood that, in some embodiments, other elements or groups of elements may replace hydrogen at the X and/or B sites.

X and Y are typically selected so as not to introduce species that impart overly undesirable properties to the material which, for example, impair device performance. Such species may include sodium, iron and gold, amongst others.

The source feed gas may be ionized to form a variety of different ion species. The ion species may include the same, or similar, boron content as the source feed gas. The ion species may also include the additional elements present in the source feed gas. For example, a source feed gas comprising XₐB_{b}Y_{c} (e.g., XₐB_{b}H_{c}) may be ionized to form ion species comprising XₐB_{b}Y_{c-1} (e.g., XₐB_{b}H_{c-1}) which may have a positive or negative charge. When the source feed gas comprises C₂B₁₀H₁₂, ionic species produced include (C₂B₁₀H₁₁)⁺. It should also be understood that the ion species may include boron and only one of the elements (e.g., Y). In some embodiments, systems of the invention include mechanisms for selecting desired ionic species from those produced for the ion beam and subsequent implantation.

It may be preferred that the source feed gas has a relatively high molecular weight which can lead to formation of ions also having relatively high molecular weight(s). For example, it may be possible to produce ions having the desired molecular weight by appropriately selecting the ionization conditions. The implant depth of an ion depends on the implantation energy and its molecular weight. Increasing the molecular weight of an ion allows use of higher implant energies to achieve the same implant depth. Thus, using source feed gases having a relatively high molecular weight can enable formation of ultra-shallow junction depths (e.g., less than 25 nm) at implant energies sufficiently high to allow operation at desirable efficiency levels. For example, when ionic species comprising (C₂B₁₀H₁₁)⁺are implanted, a relatively high implant energy (e.g., 14.5 keV) may be used. In this embodiment, the equivalent boron implant energy is about 1 keV (for the case when all of the boron atoms are present as ¹¹B so that (C₂B₁₀H₁₁)⁺has a weight of 145 amu). In some cases, it is preferred to use equivalent boron implant energies of less than 5 keV; and, in some cases, equivalent boron implant energies of less than 1 keV.

Molecular weight of the source feed gas (and the ionic species which are implanted) is determined by the number and type of atoms in the composition. In some cases, it is preferable for b in the above-noted formulas to be greater than 2; or, greater than 8. In some cases, it is preferable for c in the above-noted formulas to be greater than 2; or, greater than 8. In some embodiments, it is preferred for the molecular weight of the source feed gas (and the ionic species which are implanted) to be greater than 50 amu; or, in some cases, greater than 100 amu (e.g., about 120 amu).

It should be understood that the above-noted source feed gas compositions may be present in different isomeric forms. That is, the gases may have the same chemical formula, while having a different chemical structure. For example, the source feed gas comprising C₂B₁₀H₁₂ may be present as ortho-, meta-, or para-carborane forms. It should also be understood that the source feed gas may be present in different derivative forms.

Also, it should be understood that boron (or any other element) may be present in the source feed gas in any suitable isotope form including the naturally occurring form (e.g., ¹¹B—80%, ¹⁰B—20%) . For example, boron may be present with an atomic weight of 11 (i.e., ¹¹B) or an atomic weight of 10 (i.e., ¹⁰B). In some cases, substantially all of the boron in the source feed gas may be a single isotope ¹⁰B or ¹¹B. The invention is not limited in this regard.

In some cases, the source feed gas has a relatively high decomposition temperature. The decomposition temperature is determined, in part, by the stability of the chemical structure. The composition and structure of the source feed gas may be selected to provide thermal stability at relatively high temperatures (e.g., greater than 350° C.) which allows use of such gases in many conventional ion sources (e.g., indirectly heated cathode, Bemas) which generate such temperatures. For example, the decomposition temperature of the source feed gas may be greater than 350° C.; in some cases, greater than 500° C.; and, in some cases, greater than 750° C. In particular, source feed gases that comprise boron and at least two additional elements may be suitable for use in conventional ion sources in which relatively high temperature (e.g., greater than 350° C.) are used. However, it should be understood that the decomposition temperature depends on the specific source feed gas used and the invention is not limited in this regard.

In some cases, the source feed gas supply supplied to the ion source is generated directly from a source feed material. In these cases, the source feed gas may be generated in any suitable manner. In some cases, the source feed material may be a solid and, for example, be in a powder form. In other embodiments, the source feed material is a liquid. The source feed gas can be produced via a sublimation and/or evaporation step of a material that comprises boron and at least two additional elements. It should also be understood that the source feed gas may be conventionally available in gaseous form and can be directly supplied to the ion source without the need for the separate generation step. The manner in which the source feed gas is generated and/or supplied depends, in part, on the composition of the source feed gas.

In some embodiments, the source feed material comprises boron and at least two additional elements including any of the compositions noted above. In some of these embodiments, the source feed gas generated from the source feed material also comprises boron and at least two additional elements (e.g., XBY); however, in other embodiments, the source feed gas generated from such source feed material may not include boron and two additional elements and, for example, may only include boron and a single element (e.g., BY). In embodiments in which the source feed gas includes boron and a single element, the ion species generated may also include boron and only the single element (e.g., Y).

In some embodiments, the source feed gas comprising boron and at least two additional elements is a single gaseous compound. That is, the source feed gas is provided as a single gaseous composition. In other embodiments, the source feed gas may be a mixture of more than one type of gas which provides the source feed gas composition of boron and at least two additional elements. The more than one type of gas may be mixed prior to entering the ion source or inside of the ion source chamber.

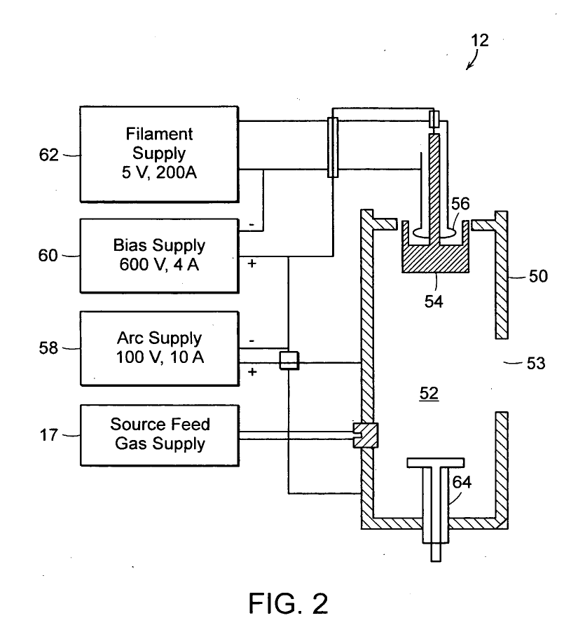

FIG. 2 illustrates ion beam source 12 according to one embodiment of the invention. Though, it should be understood that the invention is not limited to the type of ion beam source shown in FIG. 2. Other ion beam sources may be suitable as described further below.

In the illustrative embodiment, the source includes a chamber housing 50 which defines a chamber 52 and an extraction aperture 53 through which ions are extracted. A cathode 54 is positioned within the chamber. As shown, a filament 56 is positioned outside the arc chamber in close proximity to the cathode. A filament power supply 62 has output terminals connected to the filament. The filament power supply heats the filament which in turn generates electrons which are emitted from the filament. These electrons are accelerated to the cathode by a bias power supply 60 which has a positive terminal connected to the cathode and a negative terminal connected to the filament. The electrons heat the cathode which results in subsequent emission of electrons by the cathode. Thus, ion beam sources having this general configuration are known as “indirectly heated cathode” (IHC) ion sources. An arc power supply 58 has a positive terminal connected to the chamber housing and a negative terminal connected to the cathode. The power supply accelerates electrons emitted by the cathode into the plasma generated in the chamber. In the illustrative embodiment, a reflector 64 is positioned within the chamber at an end opposite the cathode. The reflector can reflect electrons emitted by the cathode, for example, in a direction towards the plasma within the chamber. In some cases, the reflector may be connected to a voltage supply which provides the reflector with a negative charge; or, the reflector may not be connected to a voltage supply and may be negatively charged by absorption of electrons.

In many embodiments, a source magnet (not shown) produces a magnetic field within the chamber. Typically, the source magnet includes poles at opposite ends of the chamber. The magnetic field results in increased interaction between the electrons emitted by the cathode and the plasma in the chamber.

Source feed gas from supply 17 is introduced into the chamber. The plasma within the chamber ionizes the source feed gas to form ionic species. A variety of ionic species may be produced which depend upon the composition of the source feed gas, as noted above, and desired ionic species may be selected for the ion beam and subsequent implantation.

It should be understood that other ion source configurations may be used in connection with the methods of the invention. For example, Bernas ion sources may be used. Also, ion sources that generate plasma using microwave or RF energy may be used. As noted above, one advantage of certain embodiments, is the ability to use the source feed gas in ion sources that generate relatively high temperatures (e.g., greater than 350° C.) without the source feed gas decomposing. However, in some embodiments, it may be preferred to use ion sources that operate at relatively low temperatures. For example, “cold wall” ion sources may be used that ionize the source feed gas by using one or more electron beams. Such ion sources have been described in U.S. Pat. No. 6,686,595 which is incorporated herein by reference.

It should also be understood that the ion source illustrated in FIG. 2 may include a variety of modifications as known to those of ordinary skill in the art.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A method of implanting ions comprising:
generating ions from a source feed gas comprising boron and at least two additional elements; and
implanting the ions in a material.

2. The method of claim 1, wherein the source feed gas comprises at least boron and carbon.

3. The method of claim 2, wherein the source feed gas further comprises at least hydrogen.

4. The method of claim 1, wherein the source feed gas comprises at least boron and hydrogen.

5. The method of claim 1, wherein the source feed gas further comprises at least a third additional element.

6. The method of claim 1, wherein the source feed gas comprises XBY, wherein X and Y each represent at least one element.

7. The method of claim 6, wherein X and/or Y are organic species.

8. The method of claim 6, wherein X and/or Y are inorganic species.

9. The method of claim 6, wherein the source feed gas comprises XB_{b}H_{c}.

10. The method of claim 6, wherein the source feed gas comprises CₐB_{b}H_{c}.

11. The method of claim 10, wherein the source feed gas comprises C₂B₁₀H₁₂.

12. The method of claim 1, wherein the source feed gas comprises a compound selected from the group consisting of NₐB_{b}H_{c}, PₐB_{b}H_{c}, AsₐB_{b}H_{c} and SbₐB_{b}H_{c}.

13. The method of claim 1, wherein the source feed gas comprises a compound selected from the group consisting of SiₐB_{b}H_{c}, GeₐB_{b}H_{c} and SnₐB_{b}H_{c}.

14. The method of claim 1, wherein the source feed gas comprises (NH₄)ₐB_{b}H_{c} or (NH₃)ₐB_{b}H_{c}.

15. The method of claim 1, further comprising producing the source feed gas by sublimation or evaporation of a source feed material.

16. The method of claim 15, wherein the source feed material is in powder form.

17. The method of claim 1, wherein the source feed gas comprising boron and at least two elements is a single gaseous composition.

18. The method of claim 1, wherein the source feed gas comprising boron and at least two elements is a mixture of more than one gas.

19. The method of claim 1, wherein the source feed gas comprises XₐB_{b}Y_{c} and b is greater than 2.

20. The method of claim 1, wherein the source feed gas comprises XₐB_{b}Y_{c} and b is greater than 8.

22. The method of claim 1, wherein the source feed gas comprises XₐB_{b}Y_{c} and c is greater than 8.

23. The method of claim 1, wherein the source feed gas has a decomposition temperature of at least 350° C.

24. The method of claim 1, further comprising accelerating the ions to an equivalent boron energy of less than 5 keV prior to implanting the ions.

25. The method of claim 1, wherein the material is a semiconductor material.

26. The method of claim 1, comprising implanting the ions in a material to form a conductive region.

27. The method of claim 1, wherein the molecular weight of the source feed gas is greater than 50 amu.

28. An ion source comprising:
a chamber housing defining a chamber; and
a source feed gas supply configured to introduce a source feed gas comprising boron and at least two additional elements into the chamber,
wherein the ion source is configured to ionize the source feed gas within the chamber.

29. The ion source of claim 28, wherein the source feed gas comprises at least boron and carbon.

30. The ion source of claim 29, wherein the source feed gas further comprises at least hydrogen.

31. The ion source of claim 28, wherein the source feed gas comprises at least boron and hydrogen.

32. The ion source of claim 28, wherein the source feed gas comprises XBY, wherein X and Y represent at least one element.

33. The ion source of claim 28, wherein the source feed gas comprises C₂B₁₀H₁₂.

34. The ion source of claim 28, wherein the source feed supply is configured to form the source feed gas from a solid comprising boron and at least two additional elements.

35. The ion source of claim 28, wherein the ion source is designed to ionize the source feed gas by generating a plasma in the chamber by thermionic electron emission.

36. The ion source of claim 28, wherein the ion source is designed to ionize the source feed gas in the chamber using RF or microwave energy.

37. The ion source of claim 28, wherein the ion source is designed to ionize the source feed gas in the chamber using one or more electron beams.

38. The ion source of claim 28, wherein the source feed gas comprising boron and at least two elements is a single gaseous composition.

39. The ion source of claim 28, wherein the source feed gas comprising boron and at least two elements is a mixture of more than one gas.

40. An ion implantation system comprising the ion source of claim 28.

41. A method of implanting ions comprising:
forming a source feed gas from a source feed material comprising boron and at least two additional elements;
generating ions from the source feed gas; and
implanting the ions in a material.

42. The method of claim 41, wherein the source feed gas comprises boron and a single element.

43. The method of claim 41, wherein the source feed gas comprises boron and at least two additional elements.

44. The method of claim 41, wherein the molecular weight of the source feed gas is greater than 50 amu.

45. An ion source comprising:
a chamber housing defining a chamber; and
a source feed gas supply configured to form a source feed gas from a source feed material comprising boron and at least two additional elements and introduce the source feed gas into the chamber,
wherein the ion source is configured to ionize the source feed gas within the chamber.

46. The ion source of claim 45, wherein the source feed gas comprises boron and a single element.

47. The ion source of claim 45, wherein the source feed gas comprises boron and at least two additional elements.

48. The ion source of claim 45, wherein the molecular weight of the source feed gas is greater than 50 amu.

49. An ion implantation system comprising the ion source of claim 45.
